(19) United States
(12) Patent Application Publication
(10) Pub. No.: US 2011/0057669 A1
(43) Pub. Date: Mar. 10, 2011

(54) Capacitive Sensor

(75) Inventor: Lin Xu, Shanghai (CN)

(73) Assignee: AMLOGIC CO., LTD., Santa Clara, CA (US)

(21) Appl. No.: 12/555,745

(22) Filed: Sep. 8, 2009

(51) Int. Cl. G01R 27/26

(52) U.S. Cl. 324/658

(57) ABSTRACT

A capacitive sensor for a digital display device comprises: one or more proximity wires; a grounding wire; wherein the DDD having a system area and a frame area; wherein the frame area is positioned around the system area; wherein the grounding wire is disposed on the DDD and forms a first area; wherein a first proximity wire is disposed outside of the first area; and wherein the first proximity wire and the grounding wire defines a first detection area of the capacity sensor.

### FIELD OF INVENTION

This invention generally relates to a capacitive sensor and, in particular, to a capacitive sensor coupled to a digital display device (“DDD”) for detecting an object adjacent to the DDD or touching the DDD.

### BACKGROUND

Capacitive sensor technology is commonly used in inputting commands to a user interface. For instance, some portable media players and mobile telephones have touch sensor controls (e.g., touch screens and touch pads), which use capacitive sensor technology.

With respect to touchscreens, touchscreens are used in conjunction with a variety of display devices, including cathode ray tubes (“CRTs”) and liquid crystal display (“LCD”) screens, as a means of inputting information into a data processing system. When placed over a display or integrated into a display, the touchscreen allows a user to select a displayed icon or element by touching the screen in a location corresponding to the desired icon or element.

Touchscreens have become common place in a variety of different applications including, for example, point-of-sale applications such as cash registers at fast-food restaurants, point-of-information applications such as department store information kiosks, ticketing applications such as airline-ticket kiosks, and other applications.

In a typical projective capacitive sensor, three transparent substrates (e.g., glass) are laminated together, each substrate having a patterned transparent resistive coating. Silver frit traces are typically used to couple the patterned coatings to the detection electronics. In one configuration, the underside of the top substrate layer has horizontal Y-measuring electrodes while the top surface of the middle substrate glass has vertical X-measuring electrodes. The upper Y-measuring electrodes can be patterned in such a way as to minimize shielding of the underlying X-measuring electrodes. The top surface of the bottom substrate layer contains a back guard electrode to isolate the sense electrodes from the electronic environment behind the touchscreen. Thus in this configuration, the X-measuring electrodes and the Y-measuring electrodes are contained within separate planes.

Furthermore, a capacitive proximity sensor for detecting a nearby object is also well known in the art such that an object need not have to actually touch the control area for it to sense the object; mere proximity to the control area is enough to sense the object. A capacitive proximity sensor converts a variation in electrostatic capacitance between a detecting electrode and a ground electrode caused by an approaching nearby object to a variation in an oscillation frequency, transforms, or linearizes the oscillation frequency into a direct current voltage, and compares the direct current voltage with a predetermined threshold value to detect the nearby object.

However, capacitive sensor technology (whether a touch sensitive sensor, a proximity sensor, or other capacitive sensors) have largely ignored applications for digital display devices (“DDDs”), e.g., digital picture frames. With respect to DDDs, it is difficult to apply capacitive sensor technology to meet the demands and unique challenges for DDDs. Those demands and challenges stem from the unique characteristics of DDDs, including structural limitations of the DDD, processing limitations of the DDD, and the costs in building a DDD.

Therefore, it is desirable to provide methods, systems, and apparatuses for a capacitive sensor coupled to a DDD that can meet the requirements and unique challenges for dynamic presentation of an image.

### SUMMARY OF INVENTION

An object of this invention is to provide a capacitive sensor that is coupled with a DDD to enable touch sensor controls of the DDD.

Another object of this invention is to provide a capacitive sensor that is coupled with a DDD to enable proximate sensor controls of the DDD.

Yet another object of this invention is to provide a capacitive sensor that is coupled with a DDD to enable motion sensor controls of the DDD.

A capacitive sensor for a DDD comprises: one or more proximity wires; a grounding wire; wherein the DDD having a system area and a frame area; wherein the frame area is positioned around the system area; wherein the grounding wire is disposed on the DDD and forms a first area; wherein a first proximity wire is disposed outside of the first area; and wherein said first proximity wire and said grounding wire defines a first detection area of said capacity sensor.

An advantage of this invention is that a capacitive sensor that is coupled with a DDD is provided to enable touch sensor controls of the DDD.

Another advantage of this invention is that a capacitive sensor that is coupled with a DDD is provided to enable proximate sensor controls of the DDD.

Yet another advantage of this invention is that a capacitive sensor that is coupled with a DDD is provided to enable motion sensor controls of the DDD.

### DESCRIPTION OF THE DRAWINGS

The foregoing and other objects, aspects, and advantages of the invention will be better understood from the following detailed description of the preferred embodiment of the invention when taken in conjunction with the accompanying drawings in which:

FIG. 1-1 illustrates an embodiment of the present invention for a capacitive sensor coupled to a digital display device.

FIG. 1-2 illustrates an embodiment of the present invention for a capacitive sensor circuit, where capacitors, Cₓ and Cₛᵤₘ, are discharged.

FIG. 1-3 illustrates an embodiment of the present invention for a capacitive sensor circuit, where a capacitor, Cₓ, is charged.

FIG. 1-4 illustrates an embodiment of the present invention for a capacitive sensor circuit, where a capacitor, Cₛᵤₘ, is charged.

FIGS. 1-5(a) to 1-5(b) illustrate a waveform for voltages, V_{PUMP+} and V_{PUMP-}, for a capacitive sensor circuit.

FIG. 2-1 illustrates a topology for a 10 segment slider with 5 channels.

FIG. 2-2 illustrates a printed circuit board (“PCB”) layout for implementing a topology for a 10 segment slider with 5 channels.

FIG. 2-3 illustrates another topology for a 10 segment slider with 5 channels.

FIG. 2-4 illustrates another PCB layout for implementing a topology for a 10 segment slider with 5 channels.

FIG. 2-5 illustrates an alternative PCB layout for two separate 5 segment sliders with 5 channels.

FIG. 2-6 illustrates a PCB layout of eight single-channel buttons.

FIG. 3-1 illustrates a PCB design of a segment unit and a divider unit.

FIG. 3-2 illustrates a PCB design with multiple segment units and divider units.

FIG. 4-1 illustrates an embodiment of the present invention for a single-proximity sensor.

FIG. 4-2 illustrates an embodiment of the present invention for a multiple-proximity sensor.

### DETAILED DESCRIPTION OF THE PREFERRED EMBODIMENTS

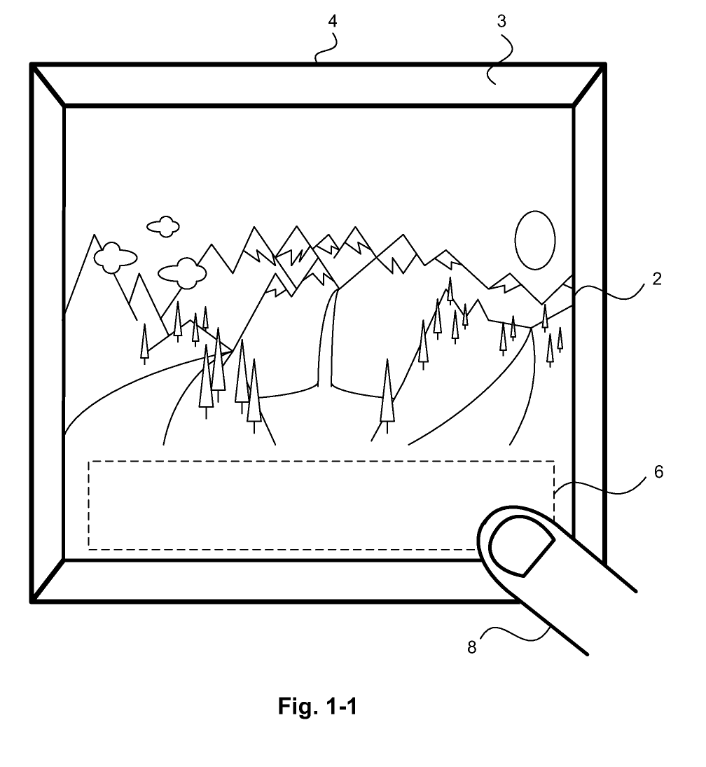

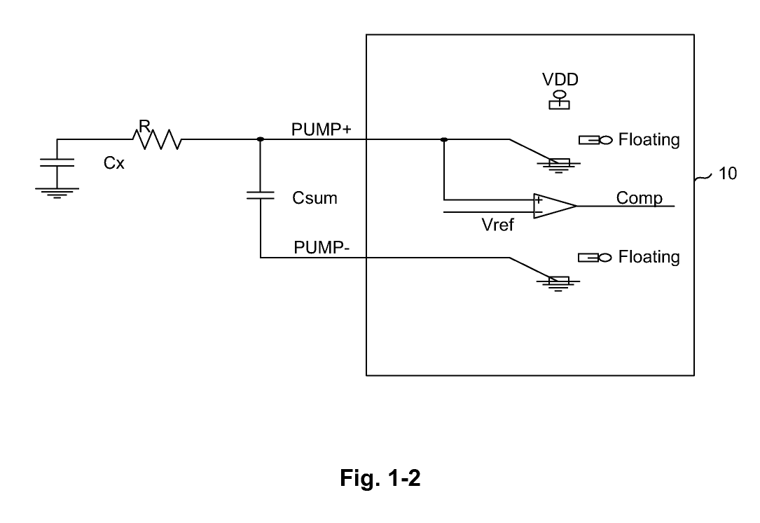

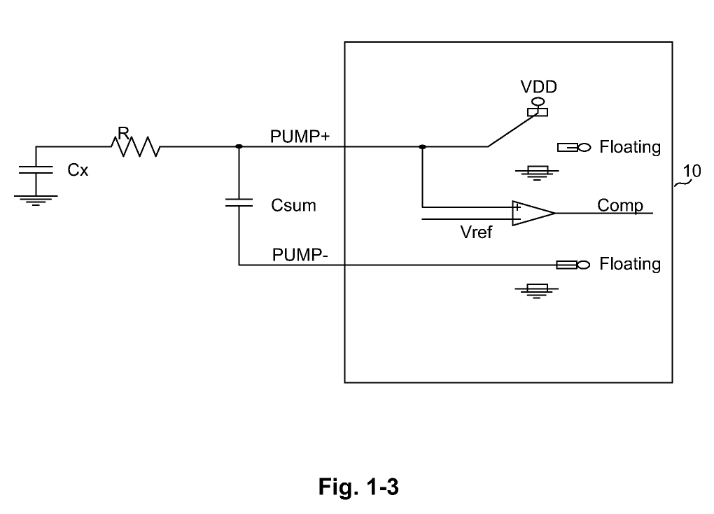

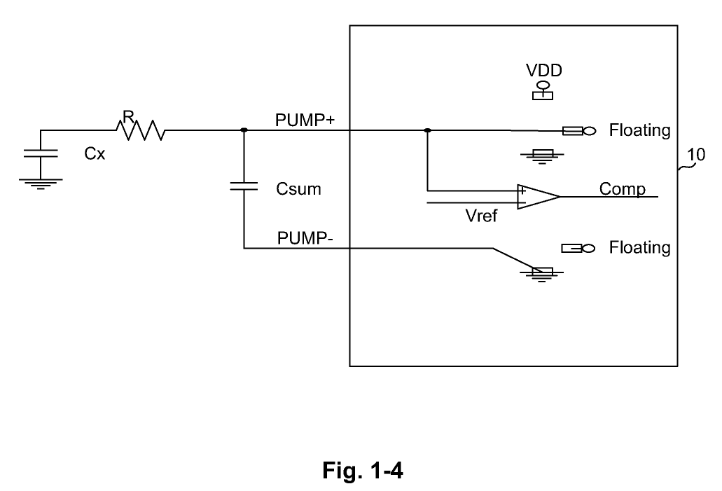

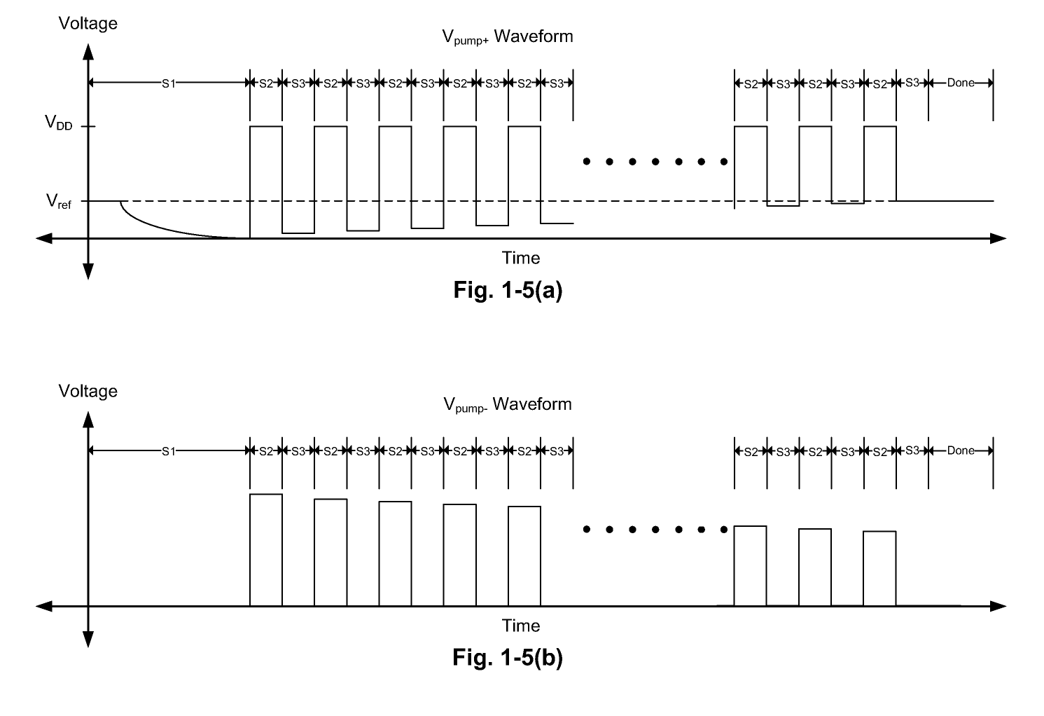

In an embodiment of the present invention, a touch (or proximity) sensitive control panel generally comprises a capacitive sensor coupled to a DDD. FIG. 1-1 illustrates a capacitive sensor coupled to a DDD. A capacitive sensor (not shown) can be mounted behind a system area 2 (e.g., a LCD screen) of a DDD 4, integrated with the DDD 4, or otherwise connected with the DDD 4. The system area 2 can be defined as the area in which an image is displayed on the DDD 4. Other components of the DDD 4 which extend beyond the system area 2 can be referred to as a frame area 3.

The capacitive sensor comprises a capacitive sensor element (e.g., one or more capacitors) in contact with the system area 2 of the DDD 4 and a capacitor measurement module (not shown) for determining the capacitance of the capacitive sensor element. The frame area 3 is positioned around the system area 2 such that the borders between the two areas 2 and 3 can overlap.

The configuration of the capacitive sensor element can define a touch (or proximity) sensitive area of the DDD 4. The touch sensitive area of the DDD 4 can be the system area 2. Alternatively or in addition, the touch sensitive area of the DDD 4 can be a smaller area 6 within the system area 2 or in the frame of the DDD 4. Furthermore, alternatively or in addition, a proximate sensitive area can be a distance away from the DDD 4. It is to be understood that the placement of a touch sensitive area and/or a proximate sensitive area are not limited to these examples; all variations and combinations that exist are also claimed.

The capacitance of the capacitive sensor element can be altered depending on the material touching the capacitive sensor element or the material adjacent to the capacitive sensor element. For instance, the presence of a user's finger 8 (or other object) positioned adjacent to the DDD 4 in a proximate sensitive area can be identified since the object can induce a measurable change in the capacitance of the capacitive sensor element. Implementation details will be discussed in further detail below.

### Working Theory for a Capacitive Sensor

FIGS. 1-2, 1-3, and 1-4 illustrate circuit diagrams for measuring the capacitance of a capacitive sensor element Cx. To aid in the understanding of the present invention, the capacitive sensor element is a capacitor. However, it is to be understood that the capacitive sensor element is not limited to a capacitor, and can be multiple capacitors or other circuits in accordance with the present invention. Also, it is understood in the art that there are other equivalent circuits for measuring a capacitive sensor element. The circuit diagrams illustrated in FIGS. 1-2, 1-3, and 1-4 are examples of the many circuits which can perform this task. Furthermore, it is understood that other circuits for measuring the capacitance of a capacitive sensor element can be used in the present invention as well.

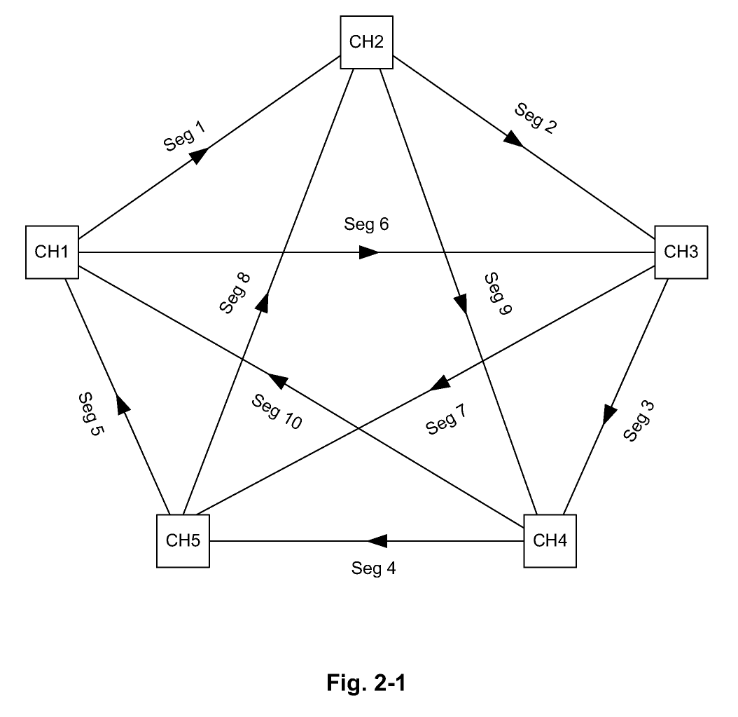

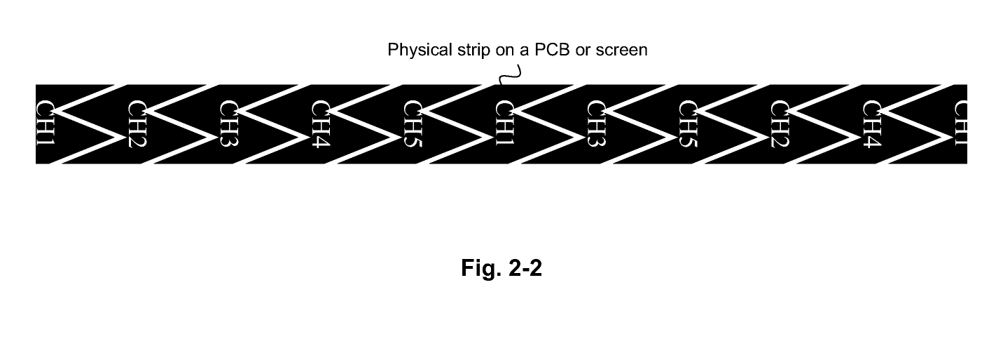

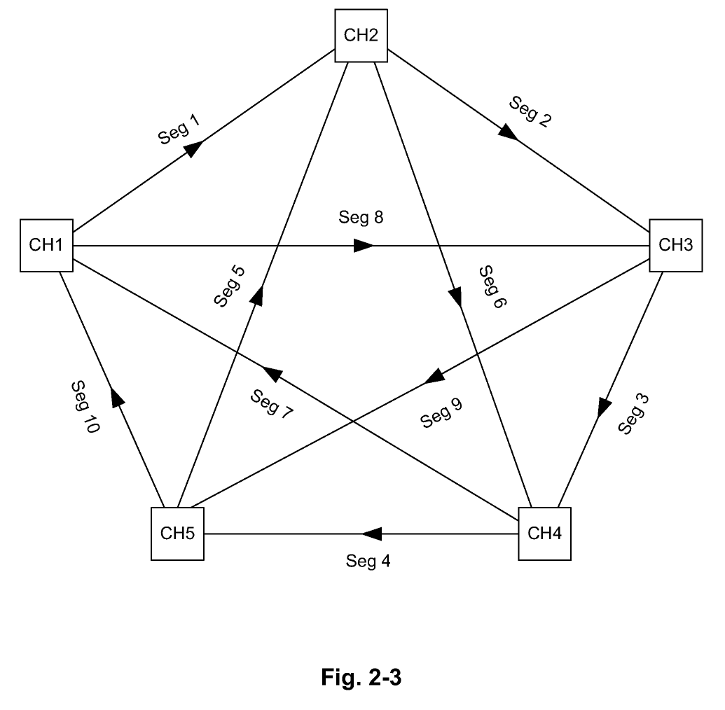

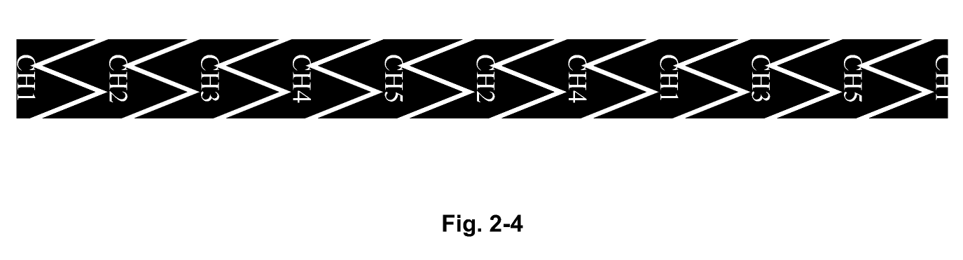

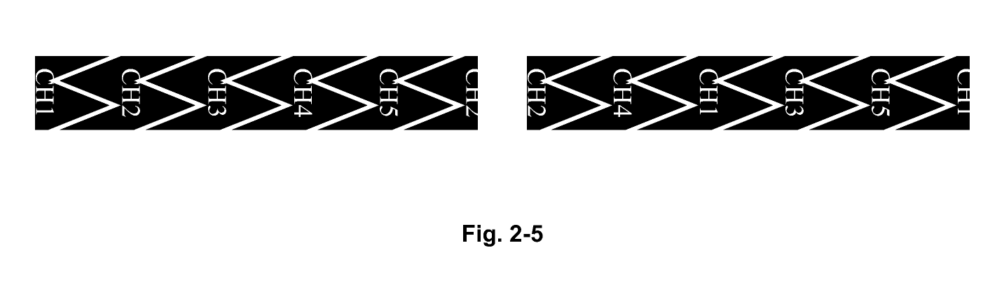

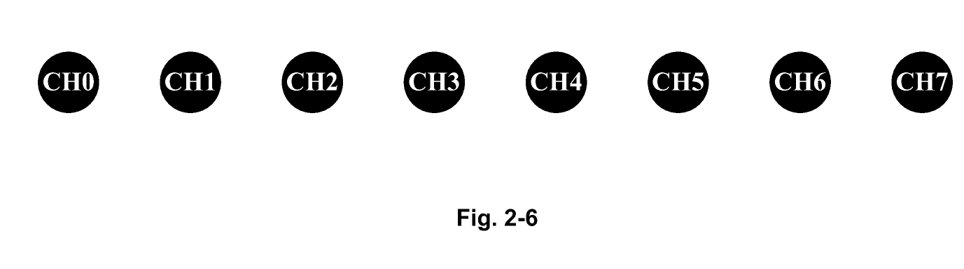

In order to measure the capacitance of a capacitive sensor element Cₓ, capacitors Cₓ and Cₛᵤₘ are discharged by setting the voltage at points PUMP+ and PUMP− to ground (a corresponding circuit diagram is illustrated in FIG. 1-2). When the voltage at the point PUMP+ is switched to a voltage VDD and the voltage at point PUMP− is switched to a floating voltage, the capacitor Cₓ is charged (a corresponding circuit diagram is illustrated in FIG. 1-3). Next, after a period of time, the voltage at the point PUMP+ is switched to the floating voltage and the voltage at the point PUMP− is switched to ground. The capacitor Cₓ then discharges into the capacitor Cₛᵤₘ (a corresponding circuit diagram is illustrated in FIG. 1-4).

The capacitor Cₓ pumps charge into the capacitor Cₛᵤₘ until a comparator, comp, determines that the voltage V_{PUMP+} at the point PUMP+ has reached a preset reference voltage V_{ref}. Once the reference voltage V_{ref} has been reached at point PUMP+, then the capacitance of capacitor Cₓ can be determined as a function of the capacitance of the capacitor Cₛᵤₘ and the number of times the capacitor Cₓ has pumped charge into the capacitor Cₛᵤₘ (see Equation (1)).

In a preferred embodiment of the present invention, a capacitance of Cₛᵤₘ should be much greater than the capacitance of Cₓ. Additionally, a hardware module 10 for the capacitive sensor can comprise: (1) two sets of switches embedded per PUMP+ and PUMP− pads; and (2) a comparator to check if V_{PUMP+} has reached the preset V_{ref}.

In a preferred embodiment of the present invention, measuring a capacitor element can be exemplified in the following steps.

In step 1 (where a corresponding circuit diagram is illustrated in FIG. 1-2), the voltage at points, PUMP+ and PUMP−, are set to ground for a first preset duration of time. In this state, the capacitors, Cₛᵤₘ and Cₓ, are discharged. Note that with respect to Cₓ and R, Cₓ may be varied for touched (Cx+Ca) or non-touched (Cx). Thus the minimum Cₓ for non-touched may be obtained and T=R*Cₓ, where Cx may be fixed once the application system design is fixed, then a duration with 10*T may be programmed for a safe full-discharge.

In step 2 (where a corresponding circuit diagram is illustrated in FIG. 1-3), the voltage at the point PUMP+ is switched to a voltage, VDD, and the voltage at point PUMP− is switched to a floating voltage for a second preset duration of time. In this state, the capacitor Cₓ is charged from VDD.

In step 3 (where a corresponding circuit diagram is illustrated in FIG. 1-4), after the second preset duration of time, the voltage at the point PUMP+ is switched to the floating voltage and the voltage at the point PUMP− is switched to ground. The capacitor Cₓ then discharges into the capacitor, Cₛᵤₘ for a third preset duration of time.

In step 4, a comparator, comp, determines whether the voltage V_{PUMP+} across the capacitor Cₛᵤₘ has reached a preset reference voltage V_{ref} i.e., the comparator is in a high state. If the comparator, comp, is in a high state, then this cycle of measurement is complete and the V_{PUMP+} has reached the voltage V_{ref}. Otherwise, the cycle restarts at step 2 and continues pumping charge from Cₓ to Cₛᵤₘ.

FIGS. 1-5(a) to 1-5(b) illustrate a waveform for each step in the measurement cycle for the voltages V_{PUMP+} and V_{PUMP-}, where the frequency may be programmable (in practice, 3 MHz may be used for touch applications and 0.75 MHz may be used for proximity applications; the key point is that the time duration must be long enough for full-charge and full-discharge, which is related to the values of Cx, Csum and R). In step 1 (S1), the voltages V_{PUMP+} and V_{PUMP-} are at ground. In step 2 (S2), the voltage V_{PUMP+} is at VDD and the V_{PUMP-} is at the floating voltage. In step 3 (S3), the voltage V_{PUMP+} is at the floating voltage and the voltage V_{PUMP-} is at ground. Finally, the voltage V_{PUMP+} is compared to the reference voltage V_{ref}. Since the voltage V_{PUMP+} is less than the reference voltage V_{ref}, the process restarts at the second step (S2) and continues pumping charge to Cₛᵤₘ until the voltage at V_{PUMP+} has reached V_{ref}. Note, each time the second step is performed (i.e., charging the capacitor Cₓ) can be considered one pumping round. Therefore, if the measurement process described above takes 10 charges for Vₛᵤₘ (the voltage V_{PUMP+} just after S3) to reach V_{ref}, then it can be said that it took 10 pumping rounds.

Once the measurement cycle is complete, the capacitance of the capacitor Cₓ can be calculated by circuit analysis based on the values of VDD, V_{ref}, capacitance of Cₛᵤₘ, and total number of pumping rounds, n, using the below formula:

Cₓ=A/n, where constant A=−Cₛᵤₘ*ln(1−V_{ref}/VDD). (1)

It is important to note that the capacitance of the capacitor Cₓ can be a capacitance of a wire, a parallel plate, or other shaped capacitor to free space or to an electrical ground. Therefore, when an object (e.g., a finger) approaches the capacitor Cₓ (e.g., a wire), an additional capacitance Cₐ is added with Cₓ, such that Equation (1) can be rewritten with the addition of Cₐ in terms of VDD, V_{ref}, capacitance of Cₛᵤₘ, and total number, m, of pumping rounds:

Cₓ+Cₐ=A/m, where constant A=−Cₛᵤₘ*ln(1−V_{ref}/VDD). (2)

By solving for Cₐ in Equation (2) and substituting Cₓ from Equation (1), the following equation can be derived:

Cₐ=A*(n−m)/(m*n), where constant A=−Cₛᵤₘ*ln(1−V_{ref}/VDD). (3)

Also, Equation (1) and Equation (2) can be written as a following capacitance ratio Cₐ/Cₓ:

Cₐ/Cₓ=(A*(n−m)/(m*n))/(A/n)=(n−m)/m. (4)

Applications for a Slider and/or a Button

Based on a capacitive sensor disclosed above or other capacitive sensors, a unique slider or virtual button can be implemented in a DDD to input commands and data to the user interface of the DDD.

The general rule to build up an efficient slider is to use an odd number of channels to generate a closed loop topology, where a path begins at a first channel, traverses the other channels, and ends at the first channel (i.e., a closed loop topology). The path from one channel to another channel can be herein referred to as a segment. Note that a channel here is comprised of a pair of PUMP+& PUMP−, which together can co-work to measure only one target capacitor Cx, and one PCB pad can be considered as a Cx. When a slider is setup with several pads, even when some of them are shared, several separated channels are needed to measure the capacitance of the separate, non-shared pads.

A number of channels, z, can be designed for a slider using the working theory given above or other variations of capacitive sensor technology. The slider can detect the position of a human finger or other object on the slider. As the finger (or other object) moves across the slider, the slider will detect the change in position by detecting the variance in the capacitance over the channels of the slider. The number of segments in a closed loop topology can be determined by the number of channels using the following equation,

z*(z−1)/2=number of segments, where z=number of channels. (5)

Thus, according to Equation (5) for a closed loop topology, 3 channels (i.e., z=3) require 3 segments; 5 channels require 10 segments; 7 channels require 21 segments; and so on and so forth.

Depending on the number of channels in a slider, the number of combinations for arranging the segments in relation to the channels to form a closed loop topology can be numerous. For instance, assuming a slider has 5 channels and 10 segments, there are many combinations of forming the closed loop topology using the 5 channels and 10 segments. Two examples for a closed loop topology for a 5 channel and a 10 segment slider are respectively illustrated in FIGS. 2-1 and 2-3.

FIG. 2-1 illustrates a closed loop topology for a path for a slider with 5 channels and 10 segments. A 10 segment slider with 5 channels can form the following path of a slider (herein referred to as “combination 1”): starting from CH1 to CH2 via segment 1; then from CH2 to CH3 via segment 2; then from CH3 to CH4 via segment 3; then from CH4 to CH5 via segment 4; then from CH5 to CH1 via segment 5; then from CH1 to CH3 via segment 6; and so on and so forth until the path ends at CH1 via segment 10.

FIG. 2-2 illustrates a printed circuit board layout diagram for a slider with 5 channels and 10 segments. A slider can be a physical strip printed on a PCB or a screen of a DDD. The arrangement of the channels along the physical strip can be any arrangement and/or combination of various channels, e.g., a path as disclosed in combination 1. Thus, by sliding an object along the physical strip starting at any channel and ending at any other channel, the object can travel along one or more segments in the path disclosed in combination 1. The slider can sense the object's change in position by comparing the relative capacitance over each of the channels.

The one or more segments detected, the order of the segments detected, and combinations thereof can be assigned as specific user inputs to the user interface of a DDD. For instance, if an object is slid from CH1 to CH5 of the slider of a DDD, then that can be assigned to indicate to the user interface of the DDD to display the next digital image or a next menu. If the object is slid from CH5 to CH1 of the slider of the DDD, then that can be assigned indicate to the user interface of the DDD to display the previous digital image or a previous menu.

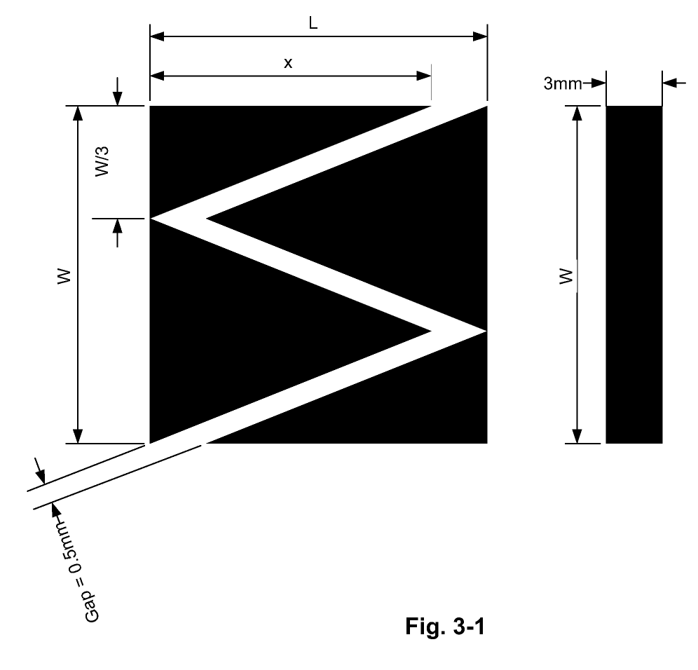

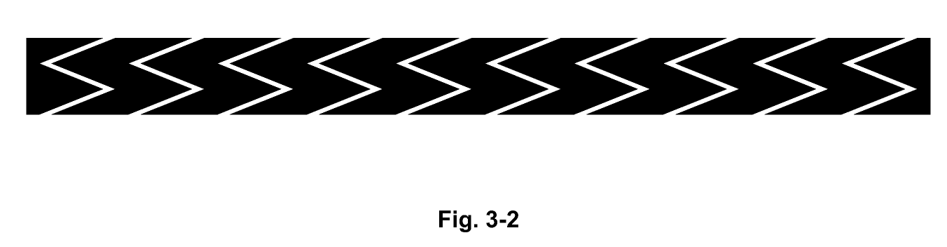

FIG. 2-3 illustrates another closed loop topology for a path for a slider with 5 channels and 10 segments. A 10 segment slider with 5 channels can form the following path of a slider (herein referred to as “combination 2”): starting from CH1 to CH2 via segment 1; then from CH2 to CH3 via segment 2; then from CH3 to CH4 via segment 3; then from CH4 to CH5 via segment 4; then from CH5 to CH2 via segment 5; then from CH2 to CH4 via segment 6; and so on and so forth until the path ends at CH1 via segment 10.

FIG. 2-4 illustrates a PCB layout diagram for a slider strip with 5 channels and 10 segments. The arrangement of the channels along the physical strip can be any arrangement and/or combination of various channels, e.g., a path as disclosed in combination 2. Thus, by sliding an object along the physical strip starting at any channel and ending at any other channel, the object can travel along one or more segments in the path disclosed in combination 2. The slider can sense this change in the object's position by comparing the relative capacitance over each of the channels.

FIG. 2-5 illustrates another embodiment of a slider, where the slider can be partitioned into 2 smaller sliders. Instead of having a continuous closed loop topology using a given number of channels, the channels can be partitioned into separate sliders with each slider having its own topology. One slider can take a path from CH1 to CH2 to CH3 to CH4 to CH5 and finally back to CH2. And another slider can take a path from CH2 to CH4 to CH1 to CH3 to CH5 and finally back to CH1. There are numerous arrangements and variations to partition the slider. In fact, the slider can be partitioned into any number of sliders as desired.

FIG. 2-6 illustrates a single-channel button, where each channel represents a distinct button. A single-channel button can be implemented with n channels having a one to one correspondence to n single-channel buttons. For instance, CH0 represents a first button; CH1 represents a second button; CH2 represents a third button; CH3 represents a forth button; CH4 represents a fifth button; and so on and so forth. Preferably, a single-channel button has a diameter ranging from 0.9 cm to 1.2 mm.

In an embodiment of the present invention, channels to buttons mapping can be one to one, many to one, one to many, two to one, one to two, so on and so forth, and any combinations thereof. For example, for user-interfaces, in a one to many channel to button relationship, a channel pushed the first time would bring up a first menu with several items, and when the button is multi-tapped, the corresponding item on the menu would be selected.

Furthermore, in an embodiment of the present invention, there can be a combination of single-channel buttons and a slider.

In another embodiment of the invention, each segment on a slider can be defined as a virtual button through software.

### Selecting a Segment Unit and a Divider Unit

FIG. 3-1 illustrates one of the many various designs for a segment unit and a divider unit. A slider comprises one or more segment units and a plurality of divider units. In designing a slider, the first step is to select the dimensions for a segment unit and the dimensions for a divider unit. The width of a segment can be denoted “W”. The width, W, can be selected based on the application for which the slider will be used. For instance, if the slider is used for detecting a finger (or similarly sized object), then the width, W, can be preferably in the range of 0.9 cm to 1.2 cm.

Each segment unit is linked to another segment unit via a divider unit. The divider unit can be preferably 3 mm in length along the slider direction and the width is same as the segment unit (i.e., the width of the divider unit is W).

The segment unit length can be denoted “L”. Thus, assuming there are 10 segment units and 11 divider units, where the length of the divider unit is preferably 3 mm, the total length of a slider can be denoted “len”. Therefore, the length L can be given by the following equation,

L=(len−3)/10. (6)

A gap can be selected to be a defined length or substantially equal to the defined length. The defined length for the gap can be dependent on the sensitivity of the slider, an object to be sensed, the speed of the object, the materials of the slider, the application the slider is used for, and other factors. With the gap length defined, preferably around 0.5 mm, the width, W, a length, X, can be determined for a segment unit. The length, X, can be given by the following equation,

X=(−b−(b²−4ac)^{0.5})/(2a), where (7)

a=W²/9−Gap², (8)

b=−2LW²/9, and (9)

c=(L²−Gap²)*W²/9. (10)

The divider unit dimensions can also be determined accordingly.

### Combining Segment Units and Divider Units

FIG. 3-2 illustrates an embodiment of the invention for generating a slider using segment units and divider units. The slider can be a combination of the segment units and the divider units. For instance, the slider can be in the following order: a divider unit, a segment unit, a divider unit, a segment unit, . . . , a divider unit, a segment unit, and a divider unit. Here, the segment units and divider units are alternated to build the slider. However, other combinations and variations can be used to build a slider.

### Applications for Proximity Sensors

In an embodiment of the present invention, the capacitive working theory explained above (or other capacitive sensor technology) can be used to implement a single-proximity sensor and a multiple-proximity sensor.

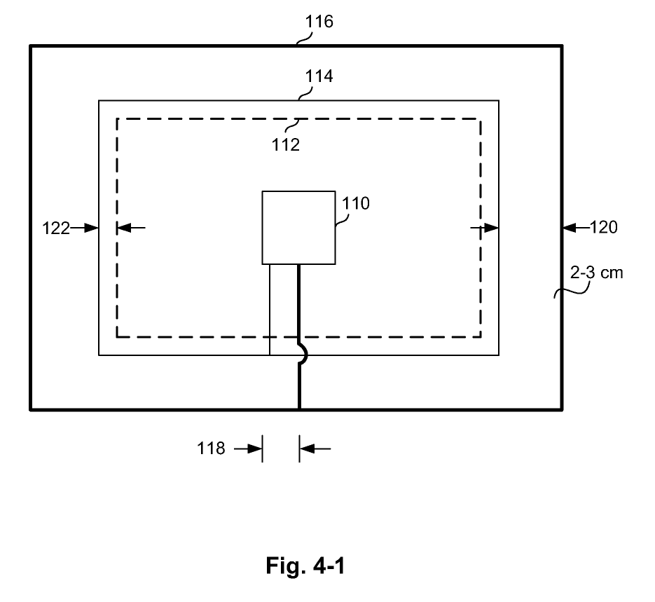

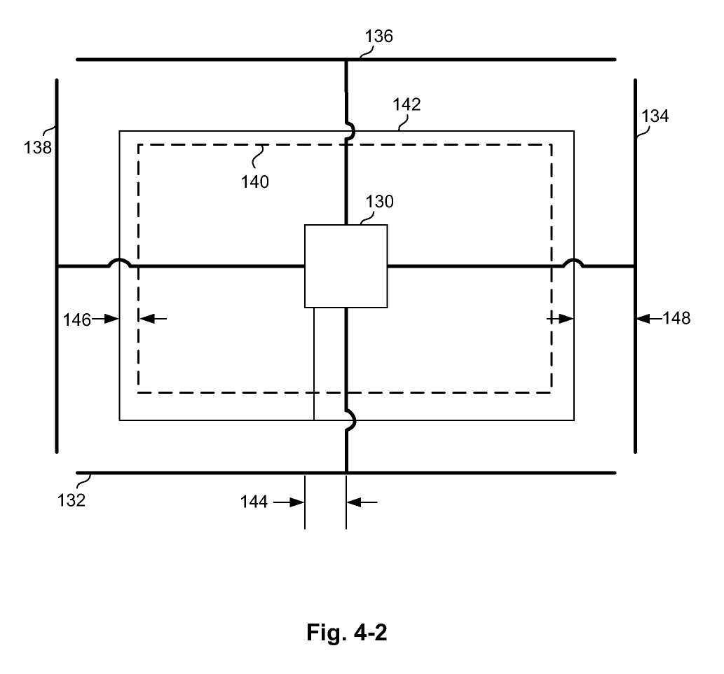

FIG. 4-1 illustrates an embodiment of the present invention for a single-proximity sensor. A single-proximity sensor can have a grounding wire 114 positioned around a system area 112 and a proximity wire 116 positioned around that grounding wire 114. The grounding wire and the proximity wire can compose a Cx. A capacitance measurement module 110 can be attached, integrated, or otherwise coupled to the system area 112. The module 110 is connected to the grounding wire 114 and connected to the proximity wire 116, where the distance between those two connections can be a distance apart, D-entry 118, where D-entry 118 may be used to obtain a smaller Cx for higher sensitivity. A distance, D-inner 122, between the grounding wire 114 and the system area 112 can be as small as 0 mm (e.g., overlapping) or larger, and can vary depending on the position of the grounding wire 114 to the system area 112. D-inner 122 is used to ensure that the grounding wire 114 fully encloses the system area 112 such that Cx references the grounding wire 114 and not the system area 112; in such manner, better uniformity can be achieved, even though the shape of the system area 112 may not be ideal. The distances D-entry 118 and D-outer 120 should be as large as possible (depending on the ID design (mechanical design) of the system). Additionally, the distance D-outer 120 should be substantially equal in length at all directions from the grounding wire 114 for uniform proximity sensing. Preferably, D-outer 120 is 2 cm to 3 cm. Note that the mechanical design of DDD limits the space for mounting grounding wire 114 at the border of the system area 112 and the proximity wire 116 outside the grounding wire 114, where the proximity wire 116 is placed in as much distance from the grounding wire 114 as possible.

The single-proximity sensor can also be coupled to a DDD, where the DDD has a frame area 4 (illustrated in FIG. 1-1) and a system area 2 (illustrated in FIG. 1-1).

Referring to FIG. 4-1, the proximity wire 116 can be coupled to the frame area of the DDD, forming a proximity area. Additionally, the grounding wire can be coupled to the frame area of the DDD or the system area of the DDD. The grounding wire 114 should be positioned within the proximity area generated by the proximity wire 116. The capacitance measurement module 110 can be attached, integrated, or coupled to the system area of the DDD. The system area of the DDD can overlap with the system area 112.

When an object (e.g., a person's body, arm, palm, finger, or other object) approaches the DDD, the proximity sensor can detect that object and alert the DDD of the proximate object. Note that the proximity wire can be implemented by various methods, e.g. an electrical wire or a slider as described above. In using a slider as the proximity wire, a multitude of user inputs may be received, each correlated to a specific function for operating the DDD.

For a multiple-proximity sensor, the multiple-proximity sensor can use individual proximity wires at different directions to not only detect an object in proximate location to the DDD, but also the direction of the object with respect to the DDD.

FIG. 4-2 illustrates a multiple-proximity sensor. A multiple-proximity sensor has multiple proximity wires 132, 134, 136, and 138 angled at different directions from a system area 140.

A grounding wire 142 is positioned around the system area 140, and the proximity wires 132, 134, 136, and 138 are positioned around that grounding wire 142. A capacitance measurement module 130 can be attached, integrated, or otherwise coupled to the system area 140. The module 130 is connected to the grounding wire 142 and connected to the proximity wires 132, 134, 136, and 138, where the distance between the grounding wire 142 and one of the proximity wires 132, 134, 136, and 138 can be referred to as a distance, D-entry 144. A distance D-inner 146 between the grounding wire 142 and the system area 140 can be as small as 0 mm (e.g., overlapping) or larger, and can vary depending on the position of a point of the grounding wire 142 relative to the system area 140. The lengths D-entry 144 and D-outer 148 should be as large as possible (upon the ID design of the system).

A multiple-proximity sensor can be coupled to a DDD. For instance, if a multiple-proximity sensor is coupled to a rectangle shaped DDD, then a proximity wire can be positioned at each of the four sides of the DDD, i.e., a top side of the DDD, a bottom side of the DDD, a left side of the DDD, and a right side of the DDD.

The multiple-proximity sensor can utilize the various proximity wires to provide for multiple detection areas where each detection area detects the proximity of an object and, by the location of the detection area on the DDD, detect the direction from which the object is approaching. For example, a multiple-proximity sensor that is coupled to a rectangle shaped DDD can detect one or more of the following actions that are within the proximity of the sensor: an object approaching from the left of the DDD; an object approaching from the right of the DDD; an object approaching from the top side of the DDD; an object approaching from the bottom of the DDD; and combinations thereof.

In using sliders as proximity wires, in addition to adding a multitude of functions as provided by the slider, user inputs now have a directional aspect. Since an object can slide entirely on the slider to use normal slider functions, in crossing into a detection area, a directional aspect is now detectable. This directional aspect adds a new dimension to the user interface. For example, a stroke down by the hand of the user and a stroke up by the hand of the user can now signify different functions. In designing the user interface, this aspect can now be incorporated, thereby providing perhaps a livelier interface.

### Algorithms for Optimization of a Capacitive Sensor

With respect to a single-chip solution for capacitive sensors coupled to a DDD, single-chip solutions are extremely susceptible to cross interference and electrical noise. In fact, signal-to-noise related issues are a bottle-neck for a single-chip solution. The following algorithms can significantly reduce such noise. In a preferred embodiment of the present invention, stream processing technology is used to implement the following algorithms. However, it is to be understood that various technologies can be used to implement the following algorithms. One example of stream processing uses IIR digital filters, acting as an analog LPF (Low Pass Filter), HPF (High Pass Filter) and BPF (Band Pass Filter). For example, if the CPU adapt a digitalized signal X every 1 mS, while X has undesired noise, where the frequency is over 200 Hz, in order to obtain the low frequency DC readings, a digital LPF with an IIR formula can be setup as follows:

Y(new)=0.125*X(new)+0.875*Y(old).

This formula calculates once for each new reading of X per 1 mS. The F0 of this LPF is 21 Hz, which is low enough to filter out undesired noise over 200 Hz. Thus a smoother reading in Y versus X can be obtained.

### Algorithm 1: Low Pass Filter (“LPF”)

According to the capacitive working theory, a given constant A in Equation (2) can be written as

A=−Csum*ln(1−V_{ref}/VDD). (11)

Thus, the capacitance of Cₓ and Cₐ can be the following equations,

Cₓ=A/n, and (12)

Cₓ+Cₐ=A/m. (13)

Based on Equations (2)-(4) and (11)-(13), it is difficult to differentiate between n values and m values.

However, when the frequency response of Cₓ+Cₐ is faster than Cₓ, the capacitor Cₓ and its corresponding number of pumps, n, should be relatively still versus Cₓ+Cₐ and their corresponding number of pumps, m. Also, in order to depress the noise mentioned above, given a function N(t) for the measured number of pumping rounds, 2 LPFs can be added:

Slow(t)=(1−1/(2̂x))*Slow(t−1)+N(t)/(2̂x); and (14)

Fast(t)=(1−1/(2̂y))*Fast(t−1)+N(t)/(2̂y). (15)

In practice, Fs, sampling frequency, is about 140 Hz, and depends on how long a whole measurement cycle will take.

If x is given, e.g., x=9, then F0 of Slow(t) is 0.04 Hz.

If y is given, e.g., y=3, then F0 of Fast(t) is 3 Hz.

Considering a function, Slow(t), for the number of pumps n and a function, Fast(t), for the number of pumps m, according to the frequency response for the Slow(t) and the Fast(t), the following equations can be derived:

Cₓ=A/Slow(t); (16)

Cₓ+Cₐ=A/Fast(t); (17)

Cₐ=A*(Slow(t)−Fast(t))/(Slow(t)*Fast(t)); and (18)

Cₐ/Cₓ=(Slow(t)−Fast(t))/Fast(t). (19)

The capacitance of Cₐ is with respect to an absolute object and the capacitance ratio of Cₐ/Cₓ is with respect to a relative object. For example, Cx of a channel is 20 pF, while a slight touch on the channel's PCB pad is 0.5 pF, then an absolute object Ca is 0.5 pF, while a relative object Ca/Cx is 0.5 pF/20 pF=2.5%. Generally, for a constant temperature and a constant humidity, a capacitive sensor should yield the same Cₐ for identical touches of an object or identical proximate locations of an object. However, temperature and humidity are not always static and can vary, which affect the capacitance of Cₐ and of Cₓ. However, the ratio of the capacitances of Cₐ and Cₓ (i.e., Cₐ/Cₓ) is not as affected. Therefore, in order to enhance the capability to adapt a capacitive sensor to a current ambient temperature and a current humidity, a capacitance ratio Cₐ/Cₓ can be used to monitor the capacitance for all channels, instead of the capacitance of Cₐ.

### Algorithm 2: Saturation on N(t)

In real world applications, electrical noise can be much higher than expected due to individual applications of a slider. To mitigate such effects, saturation of N(t) can be limited to within a reasonable range. In other words, this feature can be used to avoid false triggers during proximity detection or during touch detection.

### Algorithm 3: Thresholds Pulse Delay, and Pulse Extension

In order to calculate an accurate and smooth status report for holding and releasing, a capacitance ratio Cₐ/Cₓ can be used for all the channels of a capacitive sensor. Furthermore, three thresholds can be used in conjunction with the concepts of a pulse delay and a pulse extension.

If a capacitance ratio Cₐ/Cₓ for a channel is smaller than a noise threshold, then the capacitance ratio Cₐ/Cₓ of this channel is considered zero. Thus, the hold threshold is set.

If a capacitance ratio Cₐ/Cₓ of a channel is no less than Hold_Threshold (a hold threshold) for a time duration no less than Pulse_Delay (a pulse delay), then this channel turns to the HOLD status. For example, if Ca/Cx>=Hold_Threshold is kept continuously for a certain time (>=Pulse_Delay), then we can confirm that this channel is touched and the software will switch its status to the HOLD status. This is for digitalized anti-shocking purpose.

A release threshold can be a threshold indicating a channel should be released.

If a capacitance ratio Cₐ/Cₓ for a channel is smaller than Release_Threshold (a release threshold) for a time duration no less than Pulse_Extension (a pulse extension), then this channel is set to the RELEASE status. For example, if Ca/Cx<Release_Threshold is kept continuously for a certain time (>=Pulse_Extension), then we can confirm that this channel is released from a previous touch and the software will switch its status to the RELEASE status. This is for digitalized anti-shocking purpose.

### Algorithm 4: Long Hold Support

Since Slow(t) is continuously calculated, if a channel stays in a hold status for a prolonged period of time, a capacitance ratio Cₐ/Cₓ will be calculated down, and go back to a release status unexpectedly. To handle a long hold status, an extra order is included in the function Slow(t). Note that calculated down means as follows: since Ca/Cx=(Slow(t)−Fast(t))/Fast(t), that is Ca/Cx=Slow(t)/Fast(t)−1; when touching and holding, Fast(t) will quickly go down to the new level and kept almost no change, while Slow(t) will slowly go down to that new level a little by little, so Ca/Cx will be smaller a little by little, until the level is down to 0 finally, after a relatively longer period of time; So in HOLD status, Slow(t) is made even slower than before, or even frozen for in the same mode, therefore the HOLD status can be kept for an even longer period of time as expected.

In a release status, the function Slow(t) can be given as,

Slow(t)=(1−1/(2̂x))*Slow(t−1)+N(t)/(2̂x). (20)

In a hold status, the function Slow(t) is given as,

Slow(t)=(1−1/(2̂(x+z)))*Slow(t−1)+N(t)/(2̂(x+z)). (21)

Thus, given Fs=140 Hz, x=9, and z=3, in a release status F0 of Slow(t) is 0.04 Hz, and in a hold status F0 of Slow(t) is 0.005 Hz.

In addition, software can freeze the calculation of a Slow(t) in a hold status.

Therefore, in a hold status, Slow(t) is slower (or even frozen) than it was in a release status; thus a longer hold status can be supported.

### Algorithm 5: Common Noise

For a touch capacitive sensor, a single-touch mode can be supported, where each valid touch relies on up to 2 channels. A capacitive ratio can be calculated for each channel and ranked in order of largest to smallest. Thus, the third largest capacitance ratio for Cₐ/Cₓ of all the physically grouped channels can have a common noise,

common noise=the third largest capacitance ratio for Cₐ/Cₓ. (22)

For all channels, if a ratio Cₐ/Cₓ is larger than the common noise, the ratio of capacitances can be reset to equal Cₐ/Cₓ minus the common noise. If the ratio Cₐ/Cₓ is not larger than the common noise, then Cₐ/Cₓ can be set to zero.

For a proximity sensor, one channel of the proximity sensor is not pulled out, so that it can be used as a reference while one or more other channels are pulled out for active proximity channels. Thus, a ratio Cₐ/Cₓ of a referenced proximity channel can be used to determine a common noise of the one or more other channels. Therefore, for all active proximity channels, if the ratio Cₐ/Cₓ is larger than a common noise, then the ratio of capacitances can be set to equal Cₐ/Cₓ minus the common noise. If the ratio Cₐ/Cₓ is not larger than a common noise, then Cₐ/Cₓ can be set to zero.

Common noise is extremely useful to mitigate unexpected noise stemming from the system board for a single-chip solution.

### Algorithm 6: Kick Slow(t) Once to Follow Fast(t) Upwards or Downwards.

A capacitance of Cₓ is generally not ideal. Since the capacitance might vary, the capacitance can quickly and sharply get smaller. Or, alternatively, the capacitance can quickly and sharply get larger. The capacitance of Cₓ can vary depending on the ID design of the capacitive sensor, which may include how the touch board and proximity wires are mounted on the sensor and a corresponding DDD, what kinds of materials are used for the face plate and back plate of a frame of the DDD, ambient temperature and humidity changes, and so forth.

When the capacitance of Cₓ gets smaller quickly and sharply, N(t) gets larger and Fast(t) will also get larger than Slow(t) continuously. To sense any object that is approaching and any object touching the sensor, the capacitance ratio Cₐ/Cₓ is equal to [Slow(t)−Fast(t)]/Fast(t). When Fast(t) is bigger than Slow(t), the capacitance ratio Cₐ/Cₓ will be a negative value and can be considered having a zero value by the sensor. In other words, if the Fast(t) is larger than Slow(t) continuously, Slow(t) can be slowed to catch up before sensing an object approaching or touching. An algorithm can be added to “kick” Slow(t) to follow Fast(t) upwards if Fast(t) is larger than Slow(t) continuously for a preset duration of time, where the software will intensively and immediately set Slow(t)=Fast(t), or, otherwise, Slow(t) will need a rather longer time to achieve this.

When the capacitance of Cₓ gets larger quickly and sharply, N(t) gets smaller and Fast(t) will be much smaller than Slow(t) continuously, then the capacitive sensor will stay in a hold status for an unexpectedly long period of time, and cannot return back to a release status for further sensing. This generally happens for proximity channels. An algorithm can be added to “kick” Slow(t) to follow Fast(t) downwards just after an approaching object is sensed. Since the triggering of a proximate object is of concern, the release of a proximate object may not be of great importance.

### Algorithm 7: Position of an Object Touching (or in Proximity) to a Slider.

First, a largest capacitance ratio Cₐ/Cₓ (“Ratio_1”) and a second largest capacitance ratio Cₐ/Cₓ (“Ratio_2”) of all touch sensor channels in a slider are determined. A segment unit in the slider that is touched (or an object that is proximately located near the segment unit) can be easily located due to the slider topology described above. The exact touch point can be located on this segment using the following equation,

Loc=Len*Ratio_{—}2/(Ratio_{—}1+Ratio_{—}2) (23)

where “Len” is the length of this segment unit, and “Loc” is the length from the touch point to the divider unit of the channel which corresponds to the largest capacitance ratio Cₐ/Cₓ. For example, in 5 channels' slider applications, the ratios for Ca/Cx of all the channels are: CH0=0.1%, CH1=0.7%, CH2=0.2%, CH3=0.5%, CH4=0.1%, then the first largest ratio is CH1=0.7% and the 2nd largest ratio is CH3=0.5%, while the 3rd largest ratio CH2=0.2% is common noise. So after correction with common noise, all channels' ratio will be: CH0=0, CH1=Ratio_1=0.5%, CH2=0, CH3=Ratio_2=0.3%, and CH4=0. So the touch position is in between CH1 and CH3, which reflects the unique segment.

While the present invention has been described with reference to certain preferred embodiments or methods, it is to be understood that the present invention is not limited to such specific embodiments or methods. Rather, it is the inventor's contention that the invention be understood and construed in its broadest meaning as reflected by the following claims. Thus, these claims are to be understood as incorporating not only the preferred methods described herein but all those other and further alterations and modifications as would be apparent to those of ordinary skilled in the art.

We claim:

1. A capacitive sensor for a digital display device (“DDD”), comprising:
one or more proximity wires;
a grounding wire;
wherein the DDD having a system area and a frame area; wherein the frame area is positioned around the system area; wherein the grounding wire is disposed on the DDD and forms a first area; wherein a first proximity wire is disposed outside of the first area; and wherein said first proximity wire and said grounding wire defines a first detection area of said capacity sensor.

2. The capacitive sensor of claim 1 wherein the grounding wire and an area thereabout define an inner area sensitive to user-input.

3. The capacitive sensor of claim 1 wherein there is a distance between the grounding wire and the first proximity wire and such distance generally defines the width of an area for receiving user-input.

4. The capacitive sensor of claim 3 wherein the width is maximized.

5. The capacitive sensor of claim 1 wherein a capacitance measurement module is connected to the grounding wire via a first connection and is connected to the first proximity wire via a second connection, and wherein the distance between the first connection and the second connection define an area for receiving user-input.

6. The capacitive sensor of claim 5 wherein the distance between the first connection and the second connection is maximized.

7. The capacitive sensor of claim 1 wherein a second proximity sensor is disposed outside of the first area thereby defining a second detection area of said capacitive sensor; wherein the detection of an object in said first detection area is associated with a first function and the detection of an object in said second detection area is associated with a second function.

8. The capacitive sensor of claim 1 wherein each of the proximity wires is a slider.

9. The capacitive sensor of claim 8 wherein the slider is formed by one or more segment units and a plurality of divider units, and wherein the slider defines one or more functions.

10. The capacitive sensor of claim 7 wherein each of the proximity wires is a slider.

11. The capacitive sensor of claim 10 wherein the slider is formed by one or more segment units and a plurality of divider units, and wherein the slider defines one or more functions.

12. A capacitive sensor for a digital display device (“DDD”), comprising:
one or more proximity wires;
a grounding wire;
wherein the DDD having a system area and a frame area; wherein the frame area is positioned around the system area; wherein the grounding wire is disposed on the DDD and forms a first area; wherein a first proximity wire is disposed outside of the first area; wherein said first proximity wire and said grounding wire defines a first detection area of said capacity sensor; wherein the grounding wire and an area thereabout define an inner area sensitive to user-input; wherein a capacitance measurement module is connected to the grounding wire via a first connection and is connected to the first proximity wire via a second connection, and wherein the distance between the first connection and the second connection define an area for receiving user-input.

13. The capacitive sensor of claim 12 wherein there is a distance between the grounding wire and the first proximity wire and such distance generally defines the width of an area for receiving user-input.

14. The capacitive sensor of claim 13 wherein the width is maximized.

15. The capacitive sensor of claim 12 wherein the distance between the first connection and the second connection is maximized.

16. The capacitive sensor of claim 12 wherein a second proximity sensor is disposed outside of the first area thereby defining a second detection area of said capacitive sensor; wherein the detection of an object in said first detection area is associated with a first function and the detection of an object in said second detection area is associated with a second function.

17. The capacitive sensor of claim 12 wherein each of the proximity wires is a slider.

18. The capacitive sensor of claim 17 wherein the slider is formed by one or more segment units and a plurality of divider units, and wherein the slider defines one or more functions.

19. The capacitive sensor of claim 12 wherein said first detection area is in proximity to the DDD.

20. The capacitive sensor of claim 12 wherein said grounding wire is disposed outside the system area and wherein said grounding wire is disposed in the frame area.
